(19) United States
(12) Patent Application Publication
(10) Pub. No.: US 2010/0134327 A1
(43) Pub. Date: Jun. 3, 2010

(54) WIRELESS HAPTIC GLOVE FOR LANGUAGE AND INFORMATION TRANSFERENCE

(76) Inventors: Vincent Vinh DINH, San Diego, CA (US); Hoa Van Phan, Escondido, CA (US); Nghia Xuan Tran, San Diego, CA (US); Marion G. Ceruti, San Diego, CA (US); Tu-Anh Ton, San Diego, CA (US); LorRaine Duffy, San Diego, CA (US)

Correspondence Address: OFFICE OF PATENT COUNSEL, SPAWARSYCEN, PACIFIC CODE 36000, 53510 SILVERGATE AVE. ROOM 103, SAN DIEGO, CA, 92152-5765, US

(21) Appl. No.: 12/325,046

(22) Filed: Nov. 28, 2008

(51) Int. Cl. H03K 17/94

(52) U.S. Cl. 341/20

(57) ABSTRACT

A haptic language communication glove is disclosed containing, a wearable glove with accommodations for fingers therein, a plurality of motion sensors positioned near tips of fingers of the glove, a plurality of vibrators positioned near the tips of the fingers of the glove, a controller having communication channels to the plurality of motion sensors and plurality of vibrators, a wireless transceiver coupled to the controller, and a power supply, wherein tapping motion by the fingers of a user of the glove is interpreted as language characters of a first type, the language characters of the first type being converted into language characters of a second type for at least one of transmission and storage.

### FEDERALLY-SPONSORED RESEARCH AND DEVELOPMENT

This invention (Navy Case No. 099084) was developed with funds from the United States Department of the Navy. Licensing inquiries may be directed to the Office of Research and Technical Applications, Space and Naval Warfare Systems Center, San Diego, Code 2112, San Diego, Calif., 92152; voice 619-553-2778; email T2@spawar.navy.mil.

### BACKGROUND

This disclosure relates to communication systems. More particularly, this disclosure relates to a wireless haptic language communication glove and modes of use thereof.

### SUMMARY

The foregoing needs are met, to a great extent, by the present disclosure, wherein systems and methods are provided that in some embodiments facilitate a tactile communication device in the form of a wearable haptic language communication glove.

In accordance with one aspect of the present disclosure, a haptic language communication glove is provided, comprising: a wearable glove with accommodations for fingers therein; a plurality of motion sensors positioned near tips of fingers of the glove; a plurality of vibrators positioned near the tips of the fingers of the glove; a controller having communication channels to the plurality of motion sensors and plurality of vibrators; a wireless transceiver coupled to the controller; and a power supply, wherein tapping motion by the fingers of a user of the glove is interpreted as language characters of a first type, the language characters of the first type being converted into language characters of a second type for at least one of transmission and storage.

In accordance with another aspect of the present disclosure, a method for communicating using a haptic language communication glove is provided, comprising: detecting tapping of fingers of a wearer of the glove using a plurality of motion sensors on the glove; interpreting the tapping of the fingers as corresponding to language characters of a first type using a microcontroller on the glove; converting the language characters of the first type into language characters of a second type using the microcontroller; performing at least one of storing and transmitting the language characters of the second type.

In accordance with yet another aspect of the present disclosure, a haptic language communication glove is provided, comprising: means for covering a hand; means for detecting tapping, positioned near tips of the means for covering; means for generating vibration, positioned near the tips of the means for covering; means for computing having communication channels to the means for detecting tapping and means for generating vibration; means for wireless communication being coupled to the means for computing; and means for providing power to all of the above means, wherein tapping by fingers of a user of the glove is interpreted as language characters of a first type, the language characters of the first type being converted into language characters of a second type for at least one of transmission and storage.

### BRIEF DESCRIPTION OF THE DRAWING

FIG. 1 is a pictorial view of an exemplary haptic language communications glove.

FIG. 2 is a diagram showing a Braille to English alphabet mapping.

FIG. 3 is a diagram showing a Most Significant Bit to Least Significant Bit mapping for the Braille code corresponding to the letter “A.”

FIG. 4 is a diagram illustrating the mapping of the Braille code for the letter “B” to a 6-bit binary representation.

FIG. 5 is a diagram illustrating the mapping of the Braille code for the letter “Z” to a 6-bit binary representation.

FIG. 6 is a table showing a mapping between ASCII decimal/characters and Braille binary/decimals.

FIG. 7 is a diagram illustrating an exemplary haptic tapping mapping of the phrase “Hello World.”

FIG. 8 is a flow diagram showing an exemplary Transmit & Receive protocol.

FIG. 9 is a block/schematic diagram of an exemplary haptic language communication glove's boards and electronics configuration.

FIG. 10 is a block diagram illustrating exemplary mapping of haptic signals to data buffers.

FIG. 11 is a timing diagram illustrating exemplary output comparator signal(s) for each finger motor.

FIG. 12 is a flow chart illustrating an exemplary haptic language communication glove operation.

### DETAILED DESCRIPTION

Introduction

Presently, protective gear used by personnel in the armed forces or in space/exploration fields is known to be overly large and cumbersome. Flexibility is understandably sacrificed in order to provide the necessary degree of protection for the wearer. This is especially true of hand-related activities, where the protective glove unavoidably constrains the user's range of motion to simple grasping or opposing finger movements. In some environments speech or oral communication is restricted, and operators in such fields have resorted to using rudimentary hand gestures to communicate simple information to each other. These low-bandwidth gestures are unable to convey complex details and concepts. In such cases, the wearer can remove their gloves to type on a keyboard. The obvious limitation is that the protective suit no longer protects the wearer when the gloves are off. This compromise is further exacerbated by the fact that the need to type a message may be the most urgent when the threat of danger is at its maximum level.

Even if the protective gloves were designed to be comfortable, efficient, or possible to hold a pen or a pencil, or type on the keyboard, a limitation is that a keyboard and pen are still needed. The use of a keyboard adds another level of complication to a mission, as carrying a keyboard can be a nuisance as well as replacement equipment and parts might not readily available. Also, in some extreme environments, such as in space or in decontamination situations, the keyboard itself may be totally useless or at least too impractical to warrant consideration of use.

Prior art communication systems have primarily relied on a large CRT or LCD video monitor, or at best a hand-held monitor/device. All of these devices require the user to maintain some level of visual, line of sight contact with the display. Thus, they require the user to look in a certain direction toward the monitor, which may compromise the user's attention to an ongoing mission. Additionally, hand-held devices require the user to hold the device (eliminating the use of one hand). Other options for such hand-held devices are to have it hung on a belt until needed. Because of these glove-related limitations, there has not been much progress in the development of more sophisticated means of communications using the operator's hands.

Discussion

The above shortcomings in the field are, in many respects, addressed by the development and use of systems and methods for providing communication using a wireless haptic language communication glove. In principal, gestures enacted via the haptic language communication glove can be encoded into letters or words or abstractions thereof, and stored or transmitted wirelessly to another person. Thus communication input and reception without the use of a keyboard or a display while using protective gear can be performed.

Various details of developing a glove having related capabilities are also described in co-pending patent application no. ______, filed by the present inventor(s) on Nov. ______, 2008, titled “Static Wireless Data Glove for Gesture Processing/Recognition and Information Coding/Input,” having Attorney Docket number 098721. The contents of this co-pending application are expressly incorporated herein by reference in its entirety.

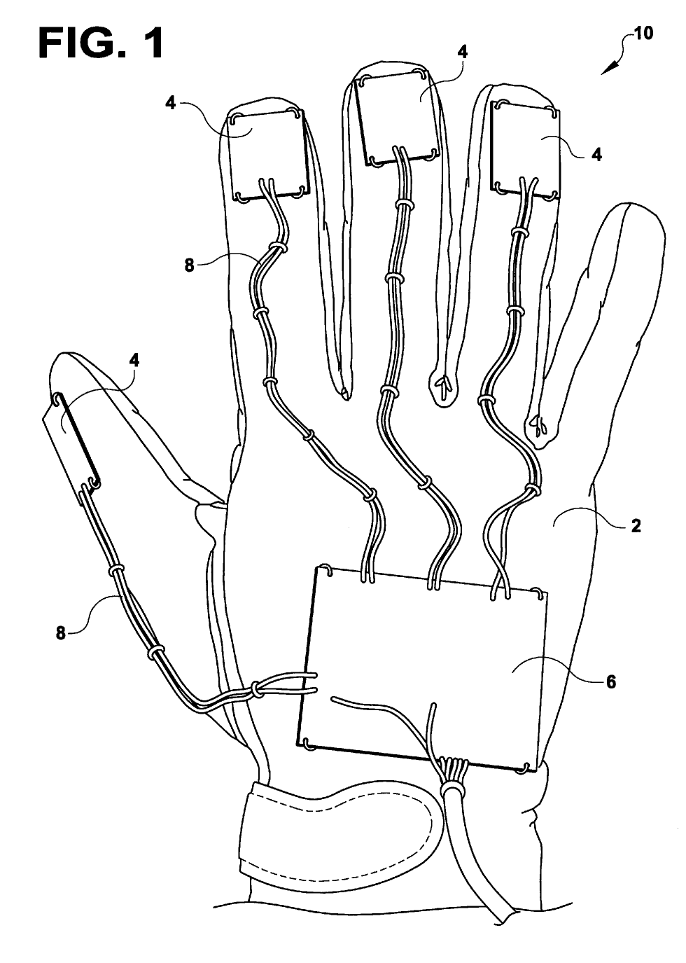

FIG. 1 is a pictorial view of an exemplary haptic language communications glove 10 that provides tactile to symbol conversion and communication. In various embodiments, tactile signals (e.g., finger movements) are mapped into characters or symbols recognizable as a communication language, reproducible by a standard keyboard. The exemplary glove 10 is shown formed from a hand covering 2 that is embedded with finger sensors 4 coupled to a controller 6 via communication lines 8 to provide sensory detection and communication. Specifically, when the glove operator provides a sensory action (for example, tapping using his/her fingers), the exemplary haptic language communications glove 10 interprets these actions as equivalent to a known code, for example, Braille codes, and the controller 6 maps them to a non-Braille code, such as, for example, ASCII codes. The information can be stored in read-only-memory (RAM), or in electrically erasable programmable ROM (EEPROM); or sent as ASCII data wirelessly to other compatible haptic language communication gloves. Conversely, when ASCII (or equivalent) codes are sent to the glove wearer, the controller 6 maps them to finger-vibrations. In practice, the finger vibrations correspond to Braille codes which can be simulated by vibrating a motor mounted on the glove's tips. In essence, tactile information is silently mapped to another domain and vice versa via the interpretation of finger movements.

The hand covering 2 for the haptic language communication glove 10 can be constructed from flexible leather-synthetic materials and optionally fitted with Velcro® fastener(s). The hand covering 2 can cover the entire hand up to the wrist, if so desired. Finger sensor(s) 4 can be mounted at the tip (above the fingernail) of the thumb, index, middle, and ring fingers. All finger sensors 4 are connected via a bus or individually to the controller 6. The controller 6, in turn is connected to a transceiver (not shown). The finger sensors 4 and controller 6 can be powered via a separate battery which may be situated on the respective boards or remotely on the transceiver board (not shown). The controller 6 reads the outputs from the finger sensors 4; interprets them as intended Braille codes; then translates the codes into ASCII information. The ASCII information is then transmitted via the transceiver to a nearby computer or to an offsite apparatus.

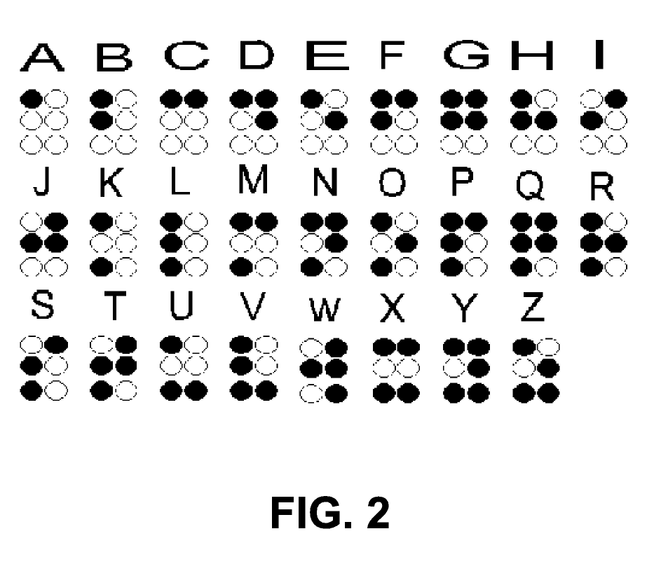

FIG. 2 is a diagram showing a Braille code to English alphabet mapping. The alphabet for Braille code is composed of two columns of adjacent elevated dots. The left column represents the high set and the right column represents the low set. The Braille reader senses the letter “A” when a single pressure on the finger is felt, corresponding to the left most and highest position. By feeling various “positions” of pressure, the entire English alphabet can be communicated.

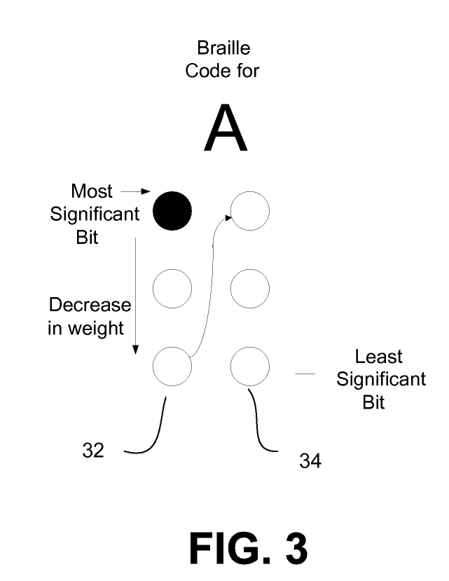

FIG. 3 is a diagram showing an exemplary Most Significant Bit to Least Significant Bit mapping for the letter “A.” Given that there are six possible pressure points to a Braille set and that they are arranged into two columns of three rows, a binary value can be assigned to the set by reading the leftmost column 32 first from the top (most significant bit—MSB) to the bottom (least significant bit—LSB) and similarly proceeding to the next column 34. Then by concatenating the sequence of bit values from the two columns, we can generate a 6 bit word, to arrive at a total binary expression.

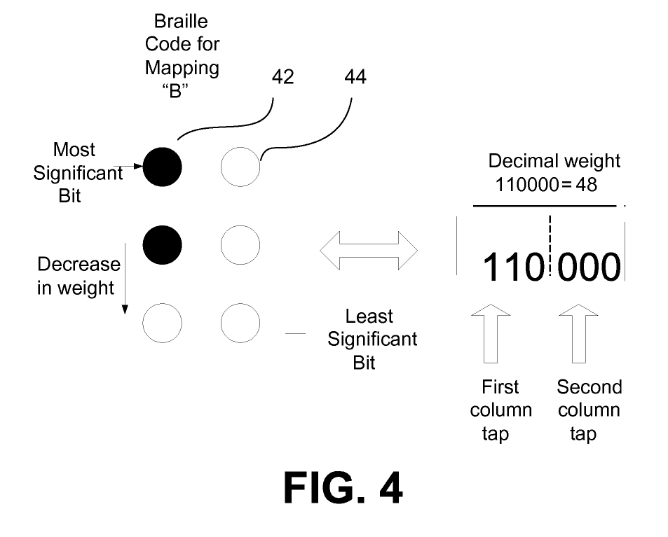

FIG. 4 is a diagram illustrating the mapping of the Braille code for the letter “B” to a 6-bit binary representation. Here, the MSB and the next lower bit are engaged in the leftmost column 42, resulting in the first column binary representation to be 110. In the next column 44, we see that none of the column elements are engaged, thus resulting in a binary representation of 000. By concatenating the two column bit values, we arrive at the expression 110000. This binary value, when converted to base 10 (decimal) is equivalent to the number 48.

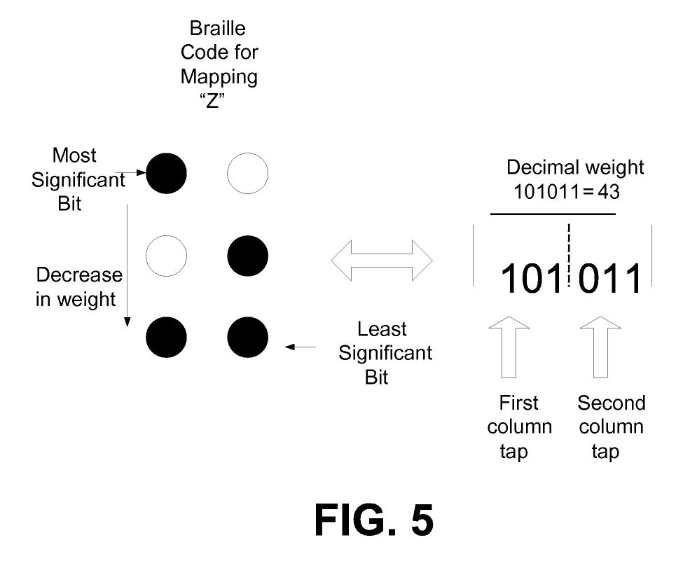

FIG. 5 is a diagram illustrating the mapping of the Braille code for letter “Z” to the 6-bit binary representation 101011, and is self-explanatory.

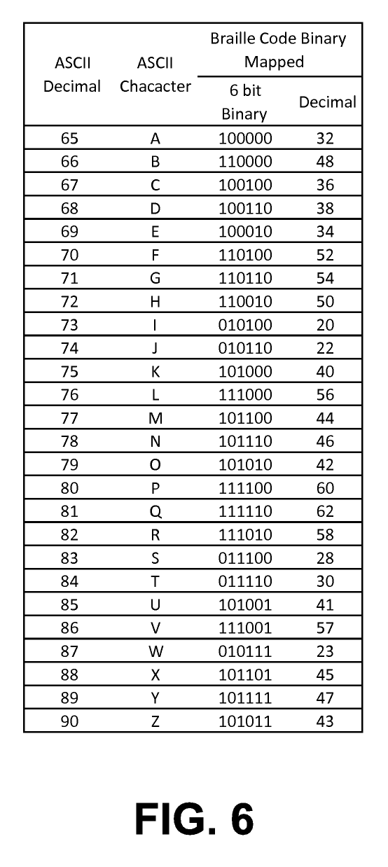

FIG. 6 is a table showing the mapping between ASCII decimal/characters and Braille binary/decimals, according to the principles described above, and is self-explanatory.

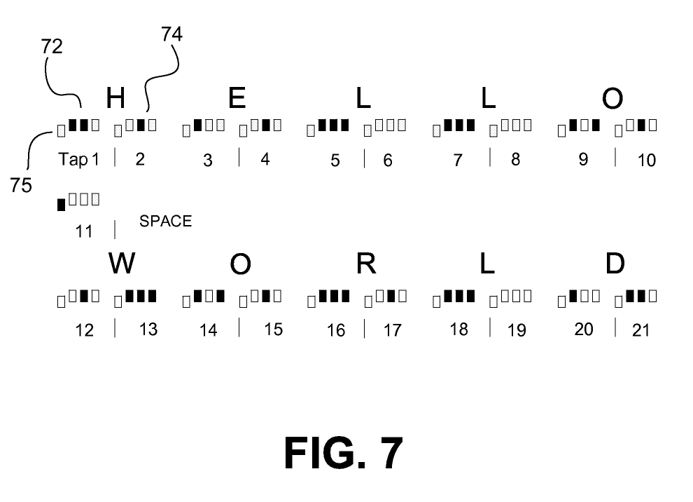

FIG. 7 illustrates an exemplary haptic language communication glove encoding for the phase “HELLO WORLD” using the mapping described above. The sets of dots shown in FIG. 7 correspond to thumb, index, middle, and ring fingers signals (e.g., taps) of the operator, with the thumb signal shown by the lower offset dot 75. The first upper trilogy of dots 72 is understood to correspond to the first column of a Braille character symbology, while the second trilogy of dots 74 is understood to correspond to the second column of the Braille character symbology. By combining adjacent pairs of the trilogy of dots, the entire set of Braille characters shown in FIG. 7 can be recreated. To accommodate the “space” delimiter between words, the thumb dot 75 is designated thereas. In this example, the dark and light dots represent a 1 and 0, respectively, and form the letters “HELLO WORLD.” Other Braille codes can be mapped to character codes, representable, as shown in this example, as ASCII codes.

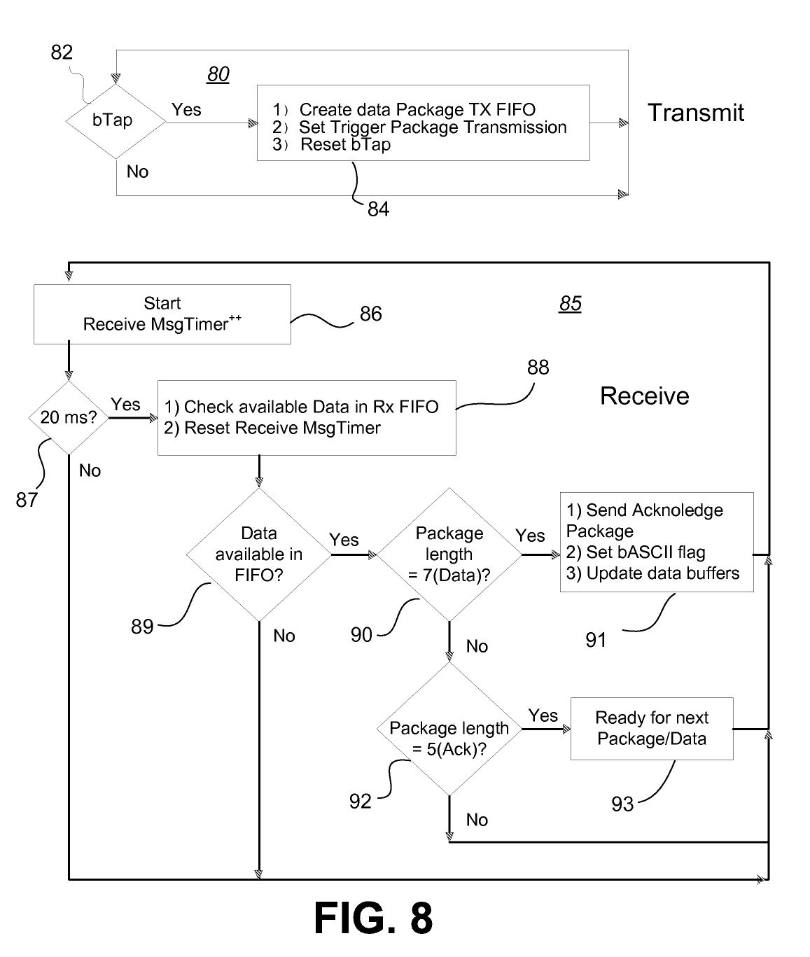

FIG. 8 is a flow diagram showing an exemplary Transmit & Receive protocol. In the transmit module 80, the bTap sensor/algorithm 82 evaluates the occurrence of finger motion and based on whether the finger motion is interpreted as a real tap or non-tap, the transmit module 80 responds accordingly. If the finger motion is determined to be a genuine tap, then the bTap sensor/algorithm 82 forwards a signal to the mapper 84 indicating a tap. The mapper 84 creates the appropriate data package for transmission and associated transmission overhead and resets the bTap sensor/algorithm 82. If the finger motion is determined to be a non-tap occurrence, then the transmit protocol flows back to detect the next finger motion.

As an example of the above transmit operation, when a operator is tapping with fingers: Thumb (T), Index (I), Middle (M) and Ring (R)—the bTap sensor/algorithm 82 constantly scans for acceleration/motion and determines if either upper or lower threshold value(s) is crossed. This crossed threshold value(s) indicates the acquisition of a tap. The combinational taps of four fingers over a certain duration of time are encoded to Braille code. The Braille code is then converted to ASCII which can be stored in memory, or sent wirelessly to a compatible haptic language communication glove 10 for reproducing the finger tapping mechanism by the vibrating motors on the finger(s).

In the receive module 85, standard ASCII-type is mapped to the Braille-type as finger vibrations. Here, the receive module 85 starts evaluating received input data based on a Receive Message Timer 86. In this example, a 20 ms timer 87 interval is used. At this designated interval, the Rx FIFO is checked for data 88 and the Receive Message Timer 86 is reset. If the designated interval period has not occurred, then the receive protocol loops back to the Receive Message Timer block 86.

However, if data is found in the Rx FIFO 89, then the data is tested to see if it is input Braille data 90. If the data is found to be of Braille format, then an Acknowledgment is sent to the transmitting entity, and a bASCII flag is set, and the data buffers are updated 91. If the data is not found to be of the Braille format, then it is tested for acknowledgment data 92. If it is determined to be acknowledgment data, then the protocol prepares for the next package/data 93 in the Rx FIFO buffer. In either event, the protocol loops back to the Receive Message Timer block 86. By using the Transmit and Receive protocols described above, full duplex communication between multiple haptic language communication gloves can be obtained.

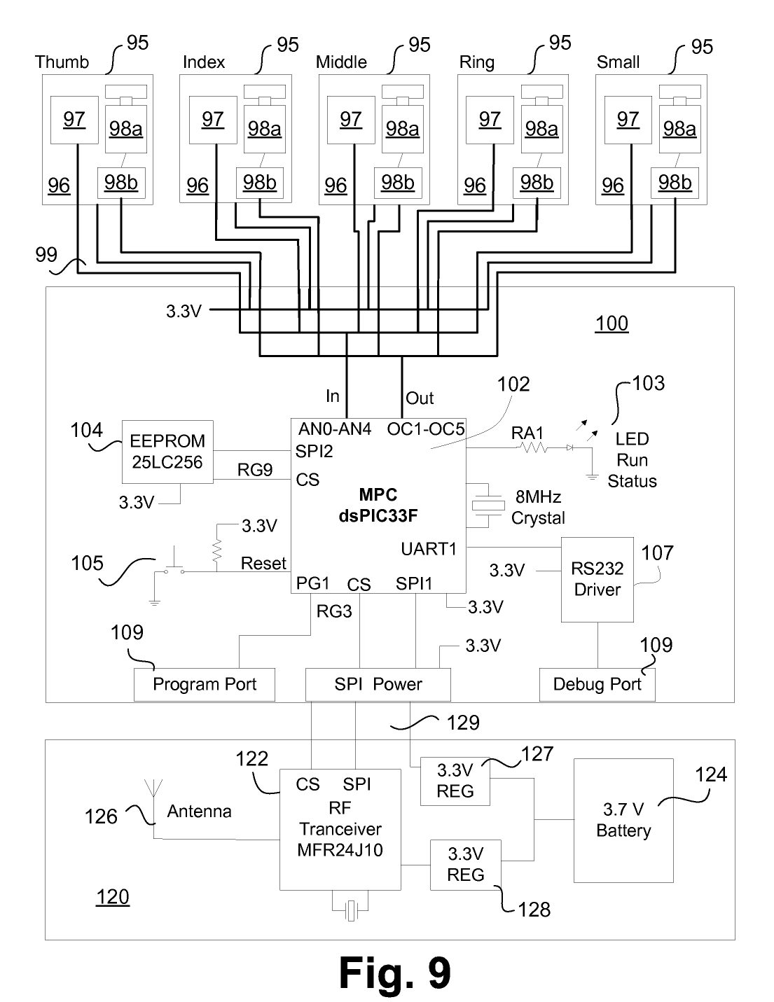

FIG. 9 is a schematic layout of an experimentally tested haptic wireless Braille glove embodiment. In this embodiment, five finger board(s) 95, hand processing board 100, and arm RF transceiver board 110 are illustrated as comprising the principle hardware boards.

On each of finger boards 90 there is a printed circuit board (PCB) 92 mounted with a motion sensor 97, such as, for example, an accelerometer, and a vibrate motor 98a with, as needed, optional motor driver 98b. The function of the motion sensor 97 is to detect tapping and the function of the vibrate motor 98a is for replaying the simulated tapping. The motion sensor 97 can be provided by use of a Z-axis accelerometer, providing either digital or analog output. In an experimental embodiment, an ADXL 330 accelerometer was utilized with successful results. The ADXL 330 is a 3-axis +/−3 g accelerometer; however, only the Z-axis mode was found necessary for detecting finger taps. An analog signal 0-3.3V output from ADXL 330 was used as indication of the acceleration of a finger. When the finger tap lightly on an object, a response pulse about 5 ms duration was measured at the Z-axis output. The vibrate motor 98a used in the experimental embodiment was a Nakimi micro-pager motor, which essentially consisted of a small DC brushless motor with an unbalanced load on its output shaft, so as to cause vibration when turned. It was rated for 1-5 VDC, however, adequate vibration occurred at 3 VDC operation. In the experimental model, a motor driver 98b was used, comprising a dsPIC33F NPN transistor with an input signal frequency of 20 KHz to control the speed of vibrate motor 98a. Each of these finger boards 95 is connected to the hand processing board 100 via signal/power line(s) 99, either directly or indirectly.

The combination of the above parts provided the necessary “sensors” for detecting finger “tapping” and also for conveying vibrations to the fingers, as demonstrated in an experimental setup. Given the various models of the components used, it should be apparent to one of ordinary skill that the models, implementation, configuration, and types of sensing, are provided above as a non-limiting example of achieving a finger motion sensor/vibrator. Thus, changes and modifications may be made to the finger board 95 elements without departing from the spirit and scope of this disclosure.

As one example, it should be evident that in some embodiments the implementation of a finger board 95 for the “small” finger may be unnecessary, as motion of the small finger, in many cases, is understood to follow the motion of the ring finger. That is, in some individuals, the small finger cannot be operated autonomously, therefore, for simplicity and accuracy, the exemplary embodiments described herein may be configured with only four finger boards, rather than five finger boards.

As should accordingly be apparent, based on the modes of operation, it may also be desirable to dispense with the use of the thumb and associated “thumb” board, as the “space” character or other character can be proxied by various operable combinations of the other three fingers. As another variation, in some embodiments, the use of a “board,” so to speak, may be unnecessary, as flexible substrates or non-board-like structures may be used to support the motion sensor 97 and vibrate motor 98a. Or, the various components of the finger board 95 may be combined to form a single module that may be attached to the glove.

Continuing with FIG. 9, the hand processing board 100 is illustrated containing a microcontroller 102 and memory 104. In the experimental model, a microcontroller model number dsPIC33FJ256MC510 microcontroller operating at 3.3V with a external clock frequency of 8 MHz was found suitable for controlling input to and receiving output from the finger boards 95. An EEPROM model 25LC256 was found suitable for use as memory 104. In this embodiment, power for the hand processing board is provided from the arm RF transceiver board 120.

In some configurations, the use of a separate memory 104 may not be necessary as some microcontrollers are fitted with sufficient memory. Or, according to design preference, the memory 104 may be situated on another board. Additional features to the hand processing board 100, some of which may be considered optional, are also illustrated in FIG. 9. For example, LED run status indicator 103 may be an optional feature. On-board reset 105 may be facilitated, as well as RS232 driver 107, and communication ports 109. Accordingly, it should be apparent to one of ordinary skill in the art that multiple features or capabilities that are not resident on the controller 102 may be accommodated for by providing the appropriate hardware module. And that the components shown and described are considered non-limiting examples. Therefore, since the embodiment shown in FIG. 9 is one of an experimental embodiment, modifications and variations to the components and/or capabilities therein may be made as being understood to be within the spirit and scope of this disclosure.

Next, FIG. 9 also illustrates a layout for the arm RF transceiver board 120, shown containing a transceiver chip 122 model MRF34J40 connected to a battery 124 (providing 3.3 V via regulator(s) 127) and to antenna 126. The transceiver chip 122 provides wireless capabilities for the hand processing board 100 via signal/power lines 129. Since each glove configuration includes a wireless capability via the arm RF transceiver board 120, each haptic language communication glove 10 can wirelessly communicate to each other, directly or through a network, for example, a Zigbee network centric, as well as to a non-haptic device, such as a computer.

In various embodiments it may be desirable to combine the features of the hand processing board 100 with the arm RF transceiver board 120, to form a single processing/wireless board. As with advances in technology, a single chip may be capable of providing the controller capabilities of the controller 102 and the transceiver/antenna features of the transceiver 122 and antenna 126. Thus, less or more components may be used according to design. Further, changes such as using a different power source (non-battery) may be envisioned to be within the scope of this disclosure.

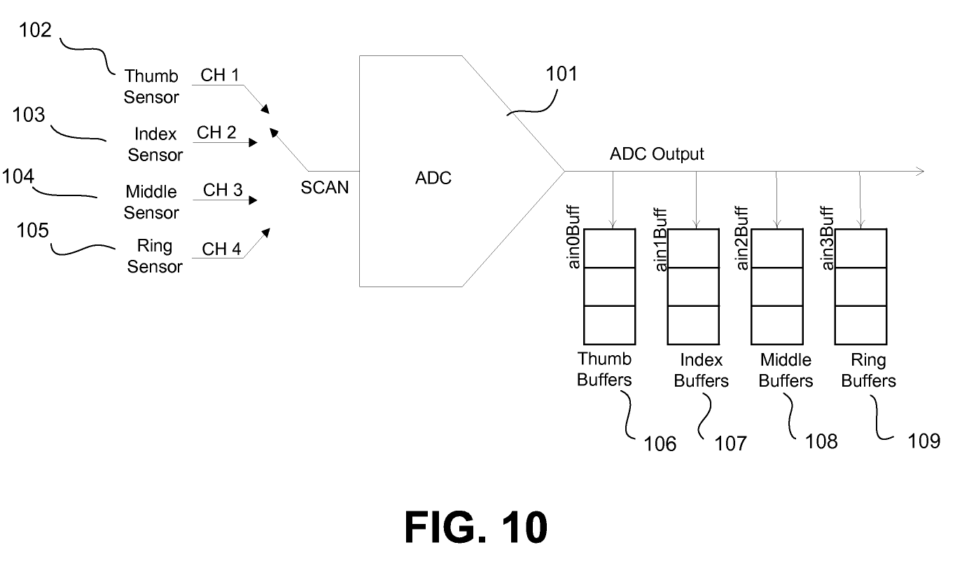

FIG. 10 is a block diagram illustrating mapping of haptic signals to data buffers. An analog-to-digital converter (ADC) 101 with multiple parallel inputs 102, 103, 104, and 105, corresponding to finger sensors on channel lines CH1, CH2, CH3, and CH4, respectively, is sampled to transfer the input signals to respective buffers 106, 107, 108, and 109. Code for the ADC 101 is written to scan and measure the acceleration of the four finger channels sequentially. Using, for example, a rate of 250 microseconds, a timer (not shown) is set to overflow which triggers the ADC 101 to stop sampling and to start conversion. Each channel/finger (102, 103, 104, 105) is scanned and converted to a digital value. Each value is stored in an array of buffers, accordingly.

In an experimental test, the sampling frequency of the ADC 101 was set at 16000000/4000=4000 Hz, which translates to a timer timeout period ( 1/4000 Hz) of 250 second. Accordingly, the period for sampling each channel becomes (frequency=4000/4=1000 Hz) 1/1000 Hz=1 millisecond. Two 8 integer buffers were assigned to each finger for past and current samples lookup. Though the above “numbers” were used in the experimental model, it should be apparent that these values may be adjusted according to design preference and, therefore modifications or changes may be made without departing from the spirit and scope of this disclosure.

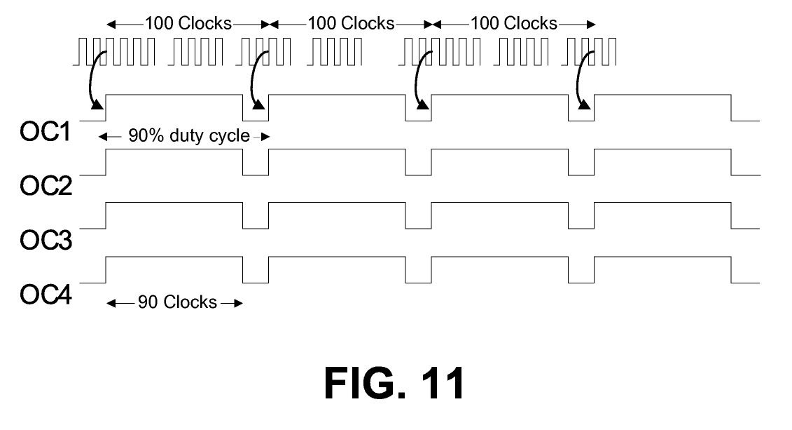

FIG. 11 is a timing diagram illustrating exemplary output comparator signal(s) for each finger motor, showing that a 90% duty cycle is employed. Though a 90% duty cycle can be used, alternative duty cycles may be used according to design preference. In the experimental embodiment used, each output comparator is set to a 90% duty cycle to create a noticeable vibration of motors upon each finger. In other word, pulses of 90% duty cycle are created and running at 20 KHz.

Based on the above disclosure, various modes of operation can be implemented in the haptic language communication gloves; the simplest modes being TALK, RECORD, and PLAYBACK, for example. In addition, they are designed to communicate wirelessly (as independent keyboard/input devices) to and from PC/MAC computers in World-Wide-Web applications. These and other variations of these modes are described below.
TYPE/RECORD Mode: the haptic language communication glove 10 is in stand-alone Mode. This Mode allows users to tap his/her fingers in simulated Braille code and store translated Braille to ASCII temporarily to built-in memory RAM.
REPLAY/PLAYBACK Mode: this allows users to replay the messages in the built-in RAM for verifications and confirmation purposes.
REMOTE/TALK Mode: this is a haptic language communication glove network centric mode with multi-user environments. This mode allows users to talk/receive wirelessly among haptic language communication glove 10 compatible user groups via a network, such as the Zigbee network centric. Also this Mode enables users to link themselves to a much wider network such as the World Wide Web (Internet). To talk wirelessly—Braille code data resident in RAM is sent to a wireless network via the on board transceiver. To receive wirelessly—Other users can send ASCII over the wireless network, which is received by the on board transceiver and subsequently replayed into Braille code via controlled motor vibrations on the fingers.
EEPROM Mode: Stand-alone Mode. This mode simply stores or saves data from built-in RAM to on-board EEPROM for later uses.

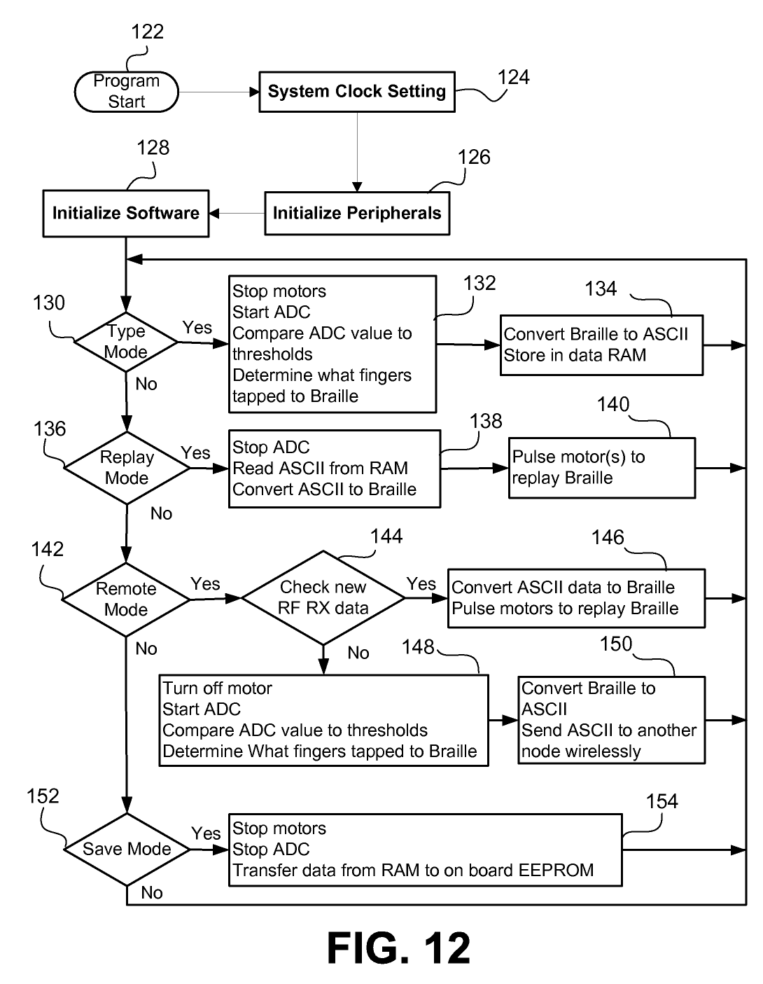

FIG. 12 is a flow chart illustrating an exemplary haptic language communication glove process. Parenthetical values presented below are those of an experimental embodiment and may vary depending on the design of the embodiment being implemented. Therefore, the parenthetical values are understood to be for demonstrative purposes and are not to be considered as limiting.

The exemplary process of FIG. 12 includes setup and control. From initiation 122, the exemplary process evaluates the system clock 124 for timing coordination (16 Mhz). Peripherals are initiated 126 thereafter (I/O port, ADC, PWM outputs, UART, controller, EEPROM). Next, software is initiated 128 (motors off, set ADC scan/read, ADC buffers, Initialize TX/RX, PHY & MAC). After setup has been completed, the process determines if the mode of operation is of the TYPE mode 130. If so, then a battery of TYPE-related operations are performed 132—vibration motors are stopped, the ADC is turned on, if off, threshold values are tested and what fingers providing data is determined. Next in step 134, the input data is converted from Braille code to ASCII code and stored in RAM. Following this step, the process returns to the Mode type test 130.

If the mode type is determined to be REPLAY mode 136, the process performs a battery of REPLAY related operations 138—stopping the ADC, reading ASCII from RAM, converting the ASCII to Braille. Next, the finger motor(s) are pulsed to replay the Braille data 140.

If the mode type is determined to be REMOTE mode 142, a check for new received RF data is performed 144. If RF data is received, then the data is converted from ASCII to Braille, and played via the finger motors 146. If RF data is not received, then a local data mode is pursued—motor(s) turned off, start ADC, compare ADC value to threshold(s), determine what fingers are operating 148. Next, the Braille data is converted to ASCII data and transmitted to another node 150.

If the mode type is determined to be SAVE mode 152, then the finger motor(s) and ADC is stopped, and data is transferred from RAM to EEPROM 154. Subsequent to this test and result, the process loops back to the Mode type test 130.

It should be appreciated that the processes described in FIG. 12 may be readily implemented in software that can be used by a variety of hardware systems, such as a microcontroller, computer, programmable ASIC, and so forth. The software encapsulating the above processes may be featured on a software disk or in memory in a hardware system. In various embodiments, the processes may be apportioned in modules or subroutines that may be executed asynchronously or in parallel by a hardware device.

Since the haptic language communication glove 10 is quiet, it can provide a suitable means of covert communication. A self-contained power supply can be attached to the haptic language communication glove to enable it to operate independently. Because there is no display, the haptic method of data reception can be implemented without the knowledge of others in the area.

The haptic language communication glove can be used in FEMA, or military personnel in “MOPP-gear” (chemical-biological protective) suits that include large gloves. Personnel wearing these suits cannot type on a keyboard. Thus, the invention also can serve as a backup for transmitting text in case a keyboard is not working. NASA may be interested in applying the invention to astronauts in space suits who have a similar limitation. Other potential uses include underwater operations, DOD special warfare team personnel in covert night operations where silence is a mission requirement, and so forth.

Other advantages in the realm of Command and Control are:
Language dependent and independent communications between humans and information systems.
Human-information system interaction in distributed computing environments.
Processing by information systems of human originated inputs and queries.
Domain dependent and independent information detection, extraction, and retrieval.
Innovative technology and component integration including multimedia presentations.
New concepts in perception and visualization.

In the realm of Communications, advantages can be:
Anti-jam/low probability of intercept links and related technologies.
Additional functionality for communicating with adaptive applications.

In the realm of Intelligence, Surveillance, Reconnaissance, and Information Operations, advantages can be:
Immersive technology to improve visualization and Human Machine Interface (HMI).

What has been described above includes examples of one or more embodiments. It is, of course, not possible to describe every conceivable combination of components or methodologies for purposes of describing the aforementioned embodiments. It will, therefore, be understood that many additional changes in the details, materials, steps and arrangement of parts, which have been herein described and illustrated to explain the nature of the invention, may be made by those skilled in the art within the principal and scope of the invention as expressed in the appended claims.

1. A haptic language communication glove, comprising:
a wearable glove with accommodations for fingers therein;
a plurality of motion sensors positioned near tips of fingers of the glove;
a plurality of vibrators positioned near the tips of the fingers of the glove;
a controller having communication channels to the plurality of motion sensors and plurality of vibrators, wherein the controller is configured to interpret tapping motion by the fingers of a user of the glove as language characters of a first type and wherein the controller is further configured to convert the language characters of the first type into language characters of a second type for at least one of transmission and storage;
a wireless transceiver coupled to the controller; and
a power supply.

2. The haptic language communication glove of claim 1, wherein the wireless transceiver is configured to wirelessly transmit language characters of the second type to a transceiver of another glove wearer.

3. The haptic language communication glove of claim 2, wherein the controller is configured to convert received language characters of the second type to language characters of the first type, and the plurality of vibrators are configured to communicate to the glove wearer characters of the second type via vibrations from the plurality of vibrators.

4. The haptic language communication glove of claim 1, wherein the power supply is a battery.

5. The haptic language communication glove of claim 1, wherein the controller is configured to store language characters of the second type in memory resident on the glove.

6. The haptic language communication glove of claim 1, wherein the language characters of the first type are Braille.

7. The haptic language communication glove of claim 1, wherein fingers of the glove correspond to at least one of a first positioning and second positioning of Braille symbology.

8. The haptic language communication glove of claim 1, wherein the language characters of the second type are American Standard Code for Information Interchange (ASCII).

9. A method for communicating using a haptic language communication glove, comprising:
detecting tapping of fingers of a wearer of the glove using a plurality of motion sensors on the glove;
interpreting the tapping of the fingers as corresponding to language characters of a first type using a microcontroller on the glove;
converting the language characters of the first type into language characters of a second type using the microcontroller;
performing at least one of storing and transmitting the language characters of the second type.

10. The method for communicating of claim 9, wherein the transmitting is performed using a wireless transceiver on the glove.

11. The method for communicating of claim 9, wherein the wireless transceiver transmits to a wireless transceiver of another glove wearer.

12. The method for communicating of claim 9, further comprising:
vibrating individual fingers of a glove wearer to communicate language characters of the first type in response to receiving language characters of the second type.

13. The method for communicating of claim 9, wherein the language characters of the second type are stored in memory resident on the glove.

14. The method for communicating of claim 9, wherein the language characters of the first type are Braille.

15. The method for communicating of claim 14, wherein a first positioning and second positioning of the Braille symbology correspond to three fingers of the glove.

16. The method for communicating of claim 9, wherein the language characters of the second type are ASCII.

17. A haptic language communication glove, comprising:
means for covering a hand;
means for detecting tapping, positioned near tips of the means for covering;
means for generating vibration, positioned near the tips of the means for covering;
means for computing having communication channels to the means for detecting tapping and means for generating vibration;
means for wireless communication being coupled to the means for computing; and
means for providing power to all of the above means, wherein tapping by fingers of a user of the glove is interpreted as language characters of a first type, the language characters of the first type being converted into language characters of a second type for at least one of transmission and storage.

18. The haptic language communication glove of claim 17, wherein received language characters of the second type are communicated to the glove wearer by converting the language characters of the second type to language characters of the first type via vibrations from the means for generating vibration.

19. The haptic language communication glove of claim 17, wherein the language characters of the first type are Braille.

20. The haptic language communication glove of claim 17, wherein the language characters of the second type are ASCII.
